(19) United States
(12) Patent Application Publication
(10) Pub. No.: US 2026/0368588 A1
(43) Pub. Date: Nov. 19, 2026

(54) QUANTUM-INFORMATION STORAGE DEVICE COMPRISING A PLURALITY OF OPTICAL WAVEGUIDES, IN PARTICULAR FOR FORMING A MULTIPLEXED QUANTUM MEMORY, METHOD OF MANUFACTURE AND USE OF SUCH A DEVICE

(71) Applicants: SORBONNE UNIVERSITE, PARIS (FR); CENTRE NATIONAL DE LA RECHERCHE SCIENTIFIQUE, PARIS (FR); ECOLE NORMALE SUPERIEURE, Paris (FR)

(72) Inventors: Julien LAURAT, PARIS (FR); Tom DARRAS, PARIS (FR)

(21) Appl. No.: 19/136,859

(22) PCT Filed: Dec. 9, 2022
(86) PCT No.: PCT/FR2022/052306

§ 371 Date: Jun. 6, 2025

(51) Int. Cl. G06N 10/40

(52) U.S. Cl. CPC G06N 10/40

(57) ABSTRACT

A quantum-information storage device (100)includes a vacuum chamber (2), a plurality of waveguides (4) configured to propagate light of wavelength λ and each having a segment of small cross section having a smallest transverse dimension less than λ, extending into the vacuum chamber. An atomic trap is configured to trap a single atomic cloud (20) around the segment of small section of the waveguides.

### TECHNICAL FIELD

The present invention relates to the field of quantum memories intended to store and read on demand quantum states transmitted by light.

More particularly, it relates to a device for storing quantum information comprising a plurality of waveguides and an atomic trap that is configured to trap a single atomic cloud around the waveguides, each waveguide allowing an independent quantum memory to be obtained.

The invention also relates to a manufacturing process and to the use of such a device.

### PRIOR ART

Storage of quantum information is an important process in quantum information science, and in particular in quantum communication or quantum computing. Quantum memories store a quantum state of light without altering its properties, and allow the light to be released on demand. In other words, they store a photonic qubit in a tangible medium and make it possible to read this qubit on demand.

Quantum memories have applications in the field of interconnection of quantum systems, and in particular allow quantum processors to be scaled up and accessed at long distances. The storage of quantum information for example permits synchronization of qubits generated by various quantum processors, with a view to efficiently creating quantum links between them and increasing their computing capacity. It also allows long-distance quantum communication to be achieved, via quantum repeaters.

In this context, a major challenge is to multiplex quantum memories, i.e. to successfully store a plurality of qubits in parallel in a single system in order to increase the success rates of various interconnection protocols within quantum information networks, whether at short or long distance.

A number of known techniques may be used to improve multiplexing capacities. These techniques are generally based on the use of a plurality of degrees of freedom of light: storage of multiple orthogonal spatial modes, of multiple time modes or of multiple frequency modes. However, these techniques generally require compromises to be made in terms of memory performance, and in particular storage efficiency, because they for example lead to a lower absorption per mode. However, absorption per mode is a parameter that is key to efficiency. In addition, certain degrees of freedom are not always compatible with certain storage protocols, for example due to their limited transverse extent or narrow spectral band.

It is known to produce a device for storing quantum information employing a fiber-optic quantum memory. By coupling an atomic cloud and a nanoscopic waveguide, it is possible to produce a fiber-optic quantum memory that has a particularly advantageous performance in terms of efficiency and of storage time.

A first demonstration of fiber-optic quantum memory was carried out with atoms cooled in a magneto-optic trap around a nanoscopic optical fiber. The corresponding device was described in the article “Demonstration of a Memory for Tightly Guided Light in an Optical Nanofiber”, Gouraud et al., Physical Review Letters, 114, 180503(2015 ). A second demonstration was obtained with atoms trapped in a dipole trap established in the evanescent field around such a fiber. It was described in the article “Storage of fiber guided light in a nanofiber-trapped ensemble of cold atoms”, Sayrin et al., Optica 2, 353(2015 ). A third demonstration of fiber-optic quantum memory, in which the atoms were also trapped in an evanescent dipole trap around the fiber, was described in the article “Waveguide-coupled single collective excitation of atomic arrays”, Corzo et al., Nature 566, 359(2019 ).

FIG. 1 shows a device for storing quantum information 1 comprising a fiber-optic quantum memory, as described in the last article. The storage device 1 comprises a vacuum chamber 2 having an inlet 3 configured to allow atoms to be introduced into the chamber. The atoms may in particular come from one or more dispensers (which for example use an electric current to heat a source of atoms and thus generate a release of atoms) and are intended to be captured in a magneto-optical trap around an optical fiber 4, then to be trapped in a dipole trap formed in the evanescent field around the optical fiber 4. The chamber also comprises two seal-tight conduits 5, 6 between the interior and exterior of the vacuum chamber, allowing the optical fiber 4 to enter and exit.

The optical fiber 4 is held in the chamber between a first holder 7 and a second holder 8, it being fastened to these holders by adhesive bonding. The holders 7, 8 are themselves held by a plate 9 that is fastened in place in the chamber.

The optical fiber 4 comprises, between the two holders 7, 8, a segment of smaller diameter, the diameter of which is less than the wavelength of the light propagating through the optical fiber, with a view to controlling the quantum memory. In the described embodiment, lasers of wavelength of about 686 nm and of about 935 nm, corresponding to wavelengths that are particularly advantageous for cesium atoms, are used for the evanescent dipole trap and the narrow segment has a diameter of about 400 nm.

During the operation of the device 1, atoms are cooled and trapped by means of a magneto-optical trap that covers the narrow segment of the optical fiber 4. When the light propagating through the fiber 4 reaches the narrow segment, much of the energy of the light flows outside the fiber due to its small size. This forms around the fiber an evanescent wave that is able to trap atoms in proximity to the fiber and interact with them.

The properties of the atomic medium around the narrow segment may be controlled by light propagating through the optical fiber 4. Quantum information may then be exchanged between the atomic medium and the light flowing through the optical fiber 4: a quantum memory is obtained.

FIG. 2 is a detail view of the conduit 5 between the exterior and interior of the vacuum chamber. The seal-tight junction between the interior and exterior is formed by a connector 17. The latter comprises a portion made of PTFE for making seal-tight contact with the optical fiber 4.

FIG. 3 shows an apparatus 10 for drawing an optical fiber 4, which apparatus is used to create the narrow segment of the optical fiber. The optical properties of the fiber during and after drawing may be determined using a laser source 11 and a photodiode 12, which are configured to inject a signal into the optical fiber 4 and to detect the signal exiting the fiber, respectively.

The apparatus 10 comprises two mechanical assemblies for applying traction, each comprising a high-precision translation stage 14 and a clamp 13. The clamps 13 hold the optical fiber 4 against holders 27, 28 positioned on the stages 14. A generator 15 of dihydrogen and of dioxygen makes it possible to generate a high-temperature flame 16 intended to heat the optical fiber 4 between the two stages 14 in order to melt it. Heating the optical fiber while moving the two stages 14 away from each other causes the optical fiber 4 to be drawn, which has the effect of decreasing the diameter of the heated portion of the optical fiber.

Thus, to produce the narrow segment, the optical fiber is heated and drawn typically over a length of a few centimeters, until a nanofiber is obtained the diameter of which is smaller than the wavelength of the light propagating through the nanofiber.

The drawing process is controlled by computer. The path of the stages 14 makes it possible to produce various drawing profiles, and in particular to control the length of the narrow segment.

The drawing is preferably carried out in such a way that the drawn fiber retains an optical transmittance greater than 99%.

The optical fiber thus prepared is then transferred to the vacuum chamber 2 after having been fastened to the first holder 7 and to the second holder 8, preferably by adhesive bonding. The holders 7, 8 are fastened to the plate 9, which is installed in the vacuum chamber 2.

A device as described with reference to FIG. 1 delivers excellent performance, in particular in terms of efficiency and storage time. However, it comprises only one quantum memory and therefore does not allow the multiplexing of quantum memories.

There is a need to improve existing devices for storing quantum information, in particular in order to allow multiplexing of quantum memories.

The aim of the invention is to meet this need at least in part.

### SUMMARY OF THE INVENTION

To do this, the invention relates, according to one of its aspects, to a device for storing quantum information, comprising:
a vacuum chamber,
a plurality of waveguides that are configured to propagate light of wavelength 2 and that each contain a segment of narrower cross section having a smallest transverse dimension less than λ, the plurality of waveguides extending into the vacuum chamber,
an atomic trap configured to trap a single atomic cloud around the segment of narrower cross section of the waveguides.

By “vacuum chamber”, what is meant is a chamber configured to allow a vacuum corresponding to pressures of 10⁻⁸ torr or less to be generated.

The invention advantageously allows the performance of prior-art quantum memories to be preserved while parallelizing a plurality of independent memories in the same device. In particular, a single atomic trap is used to produce a high number of independent memories.

It is based on installation of a plurality of waveguides that are coupled to atoms into a vacuum chamber, the atoms preferably being laser-cooled, and preferably having a temperature of less than 100 μK, and more preferably less than 20 μK.

By parallelizing fiber-optic quantum memories, the individual performance of the memories may be maintained. A single device thus allows a high number of individually accessible memories to be obtained. In addition, these memories are intrinsically fiber-optic.

The cross section of the segments of narrower cross section may in particular have a smallest dimension of between 300 nm and 500 nm, and advantageously of between 350 nm and 450 nm.

The plurality of waveguides is configured to transmit at least one emission of wavelength λ, which emission is intended to form a dipole trap that will trap some of the plurality of atoms. Specifically, in the operating configuration, some of the plurality of atoms forming part of the atomic cloud obtained using the atomic trap, which may in particular be a magneto-optical trap (MOT), forms an atomic medium in immediate proximity to each narrow segment of the waveguides. The at least one emission of wavelength λ flowing through the narrow segments and partly outside of these segments allows dipole traps that will trap atoms of the atomic cloud in the evanescent field around these segments to be created. Thus, the value of λ in particular depends on the composition of the atomic cloud. The wavelength λ is for example between 400 and 1000 nm.

The light propagating through the waveguides may be centered on one or more wavelengths. A dipole trap is typically formed by means of two lasers of different wavelengths, one being detuned into the red with respect to a resonant frequency of the atoms and the other into the blue.

Once the dipole trap has been installed, other wavelengths may be propagated through the waveguides. In particular, another wavelength is used to store quantum information in the memory. One or more other wavelengths may also be used to produce control fields, for example with a view to implementing an absorptive memory protocol, such as for example a protocol based on electromagnetically induced transparency (EIT), or an emissive memory protocol, such as a protocol based on the Duan-Lukin-Cirac-Zoller protocol.

A device for storing quantum information according to the invention may also have one or more of the following optional features:
the segment of narrower cross section of each waveguide is placed at less than 250 μm from a segment of narrower cross section of an adjacent waveguide, and preferably at less than 100 μm and more preferably at less than 5 μm, and at greater than 1 μm and preferably at greater than 3 μm;
the waveguides are placed, viewed in cross section, at the nodes of a square or hexagonal grid, or on concentric and preferably homothetic lines that in particular are circular or polygonal, and in particular hexagonal;
the segments of narrower cross section are parallel to one another;
the waveguides are optical fibers;
the waveguides are fastened in the vacuum chamber to a first holder and to a second holder, preferably by adhesive bonding, on either side of the segment of narrower cross section of the waveguides;
the device comprises a plurality of stacked first holders and of stacked second holders, the stacked holders making it possible to position the guides at various levels in the vacuum chamber;
the first holder and second holder comprise a plurality of notches, in particular V-shaped notches, in which the guides are able to be at least partially received; such notches may position the guides laterally precisely;
the segment of narrower cross section of the waveguides is circular in cross section and has a diameter between 300 nm and 500 nm;
the waveguides are lithographically patterned nanoscopic structures, in particular structures comprising structuring of photonic-crystal type. Such waveguides may in particular be made of silicon nitride SiN or gallium-indium phosphide GaInP. Optical and e-beam lithography techniques may be used to obtain these waveguides;
the atomic trap comprises two coils, called longitudinal coils, arranged outside the chamber and extending along the longitudinal axis of the waveguides on either side thereof, the longitudinal coils being configured to produce a magnetic-field gradient trapping the atomic cloud;
the atomic trap comprises two coils, called additional coils, arranged outside the chamber in a plane perpendicular to a plane containing the two longitudinal coils and extending along the longitudinal axis of the waveguides on either side thereof, the additional coils being configured to produce a magnetic-field gradient trapping the atomic cloud;
the longitudinal coils and/or additional coils are rectangular coils;
the atomic trap comprises one or more lasers configured to cool the atomic cloud, preferably to a temperature of 100 μK or less;
the vacuum chamber comprises two seal-tight conduits configured to allow the waveguides to enter and exit, the seal-tight conduits preferably comprising a portion made of PTFE for making seal-tight contact with the waveguides.

The invention also relates to a process for manufacturing a device for storing quantum information according to the invention, comprising the steps of:
(a) hot drawing and fastening after drawing between two holders a plurality of optical fibers, so as to obtain the plurality of optical fibers having a segment of narrower cross section;
(b) placing the plurality of optical fibers in the vacuum chamber.

Lastly, the invention relates to the use of a device for storing quantum information according to the invention, comprising the steps of:
(a1) forming a vacuum in the vacuum chamber;
(b1) introducing a plurality of atoms, preferably cesium or rubidium, into the vacuum chamber;
(c1) trapping the plurality of atoms around the segments of narrower cross section of the waveguides by means of the atomic trap to form the atomic cloud.

Preferably, the use comprises, after step (c1), a step (d1) of propagating, through each waveguide, light of wavelength greater than the smallest transverse dimension of the segment of narrower cross section of the waveguides so as to create a dipole trap around each waveguide.

More preferably, the use comprises, after step (d1), a step (e1) of transferring quantum information between laser emissions propagating through each of the waveguides and a portion of the atomic cloud trapped around the segment of narrower cross section of each of the waveguides, in such a way as to achieve multiplexing of quantum memories.

### BRIEF DESCRIPTION OF THE DRAWINGS

FIG. 1 shows a device for storing quantum information comprising a fiber-optic quantum memory according to the prior art.

FIG. 2 is a detail view of a conduit for passing an optical fiber between the exterior and interior of the ultra-high vacuum chamber of the device of FIG. 1.

FIG. 3 shows an apparatus for drawing an optical fiber according to the prior art.

FIG. 4 shows a device for storing quantum information according to the invention.

FIG. 5 is a cross-sectional view of a stack of first holders to which optical fibers are fastened.

FIG. 6 FIG. 7 FIG. 8 FIGS. 5 to 8 are cross-sectional views of various arrangements of a plurality of optical fibers that may be implemented in a storage device according to the invention.

FIG. 9 shows a vacuum chamber of a device comprising cooling laser beams.

### DETAILED DESCRIPTION

Throughout the present application, the terms “vertical” and “horizontal” are to be understood with reference to a device for storing quantum information according to the invention in an operating configuration, in which the waveguides extend substantially horizontally between the first holder 7 and the second holder 8. Of course, the waveguides may be oriented differently.

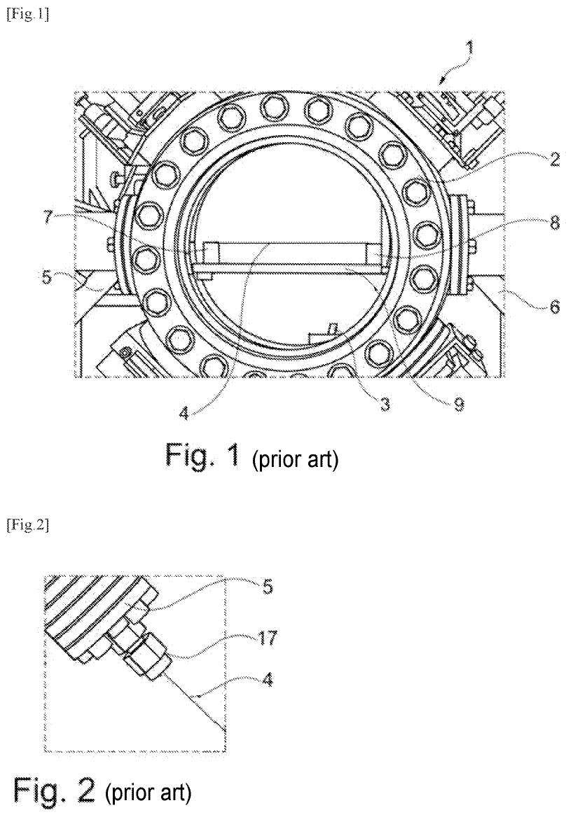

FIGS. 1 to 3 have already been described in the preamble and will not be described again below. The same reference numbers are used below to designate identical or similar elements.

FIG. 4 illustrates a device 100 for storing quantum information. The device 100 comprises a vacuum chamber 2, which is preferably made of metal, glass or a combination of these two materials.

The vacuum chamber 2 comprises an inlet 3 configured to allow a plurality of atoms to enter the chamber once the vacuum has been generated. The plurality of atoms is intended to form an atomic cloud within the chamber.

The chamber 2 further comprises seal-tight conduits 5, 6 allowing a plurality of waveguides to enter and exit. In the embodiment illustrated, the waveguides are optical fibers 4.

The optical fibers 4 are drawn fibers, i.e. fibers comprising a narrow segment, of smaller diameter, lying within the vacuum chamber 2. The diameter of the optical fibers in the non-narrow segments is typically between 100 μm and 150 μm. The narrow segments are configured to have a diameter smaller than the wavelengths of the light propagating through the optical fibers, with a view to loading the dipole traps with some of the atoms of the atomic cloud and to controlling the quantum memories. Thus, some of the energy carried by the light is localized around the narrow segments and forms an evanescent field suitable for forming the dipole traps. Preferably, the diameter of the narrow segments is between 25% and 75% of these wavelengths. This diameter is for example between 300 nm and 500 nm, the light sources used for example having wavelengths between 600 nm and 1000 nm.

The narrow segments advantageously have a length greater than or equal to 0.1 cm, 0.5 cm or 1 cm and less than or equal to 5 cm, 3 cm or 1 cm.

In one embodiment, lasers having wavelengths of 686 nm and 935 nm are used. These wavelengths are particularly suitable for manipulation of an atomic medium consisting of cesium atoms, in particular with a view to creating dipole traps. However, other wavelengths may be used.

In the operating configuration, the device 100 comprises a single atomic cloud 20 enveloping the optical fibers 4 or at least their narrow segment. Particularly advantageously, the device 100 makes it possible to use a single atomic trap to form the atomic cloud and load a high number of dipole traps.

The atomic cloud 20 comprises alkali-metal atoms, and advantageously cesium or rubidium atoms. Preferably, it comprises only cesium atoms or only rubidium atoms.

The atomic cloud 20 is preferably cold, i.e. has a temperature below 100 μK.

The atomic cloud 20 extends along the longitudinal axis of the waveguides and preferably has a length of between 0.5 cm and 5 cm and an extent in a transverse direction of between 1 mm and 5 mm. The atomic cloud may have an ovoid shape, its extent in the transverse direction being maximum at mid-length and minimum at its axial ends. In order to cover a large volume and therefore maximize the number of narrower segments of waveguides located in the cloud, it is advantageous to maximize the elongation of the atomic cloud and its transverse size.

The device 100 comprises an atomic trap configured to trap the atoms introduced into the vacuum chamber to form the atomic cloud 20 around the narrow segment of the waveguides 4. In the example illustrated in FIG. 4, the atomic trap is a magneto-optical trap and comprises two longitudinal coils 24, which are preferably rectangular, which are elongate in the direction in which the waveguides 4 extend and which are placed on either side of the vacuum chamber. Optionally, it also comprises two additional rectangular coils, which are elongate in the direction in which the waveguides 4 extend, and which are placed on either side of the vacuum chamber in a plane perpendicular to the plane containing the two longitudinal coils 24.

The additional rectangular coils advantageously allow the elongation of the atomic cloud to be increased.

The rectangular nature of all of the coils also promotes elongation of the atomic cloud.

The atomic trap advantageously comprises one or more cooling lasers configured to cool the atomic cloud.

The initial atomic trap could also be another type of trap, in particular a magnetic trap or a dipole trap formed using at least one additional laser beam. This additional laser beam would have a wavelength detuned with respect to the atomic resonance and would be directed through free space toward the narrower segments of the waveguides.

When the atomic cloud 20 has formed around the waveguides, propagation of light of a well-chosen wavelength depending on the composition of the atomic cloud makes it possible to create dipole traps around the narrow segments of the waveguides and to manipulate the properties of the atomic medium in these dipole traps.

The waveguides are independent of one another. A multiplexed quantum memory comprising as many individual quantum memories as waveguides is thus obtained. Advantageously, a single atomic cloud is used to load all of the dipole traps: this results in a significant saving in terms of the resources required to achieve the multiplexed quantum memory.

### Drawing of the Optical Fibers

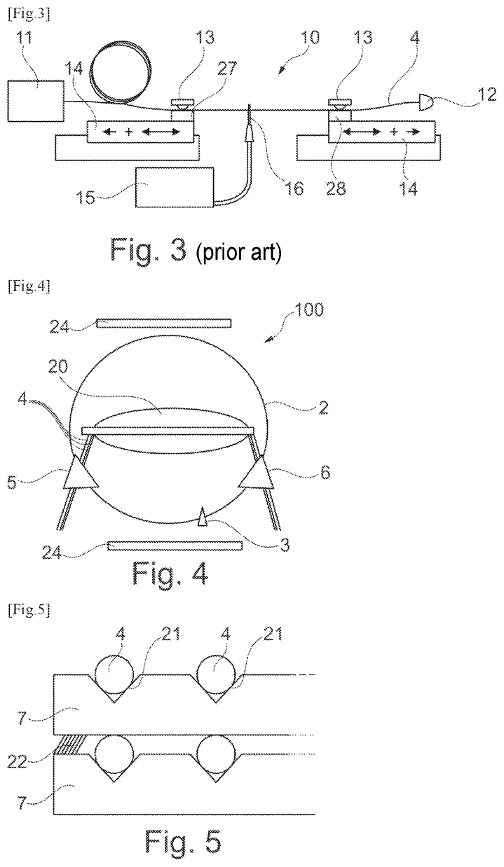

The optical fibers 4 may be drawn individually on a drawing apparatus 10 according to the drawing process described with reference to FIG. 3.

### Micro-Positioning of the Holders and Fastening of the Fibers

Once drawn on the drawing apparatus, the optical fiber 4 is positioned and fastened to a first holder 7 and to a second holder 8, the segment of narrower cross section of the fiber being placed between the holders 7, 8.

Before a fiber is positioned, the holders 7, 8 may be placed on high-precision translational stages to micro-position the holders.

Preferably, the holders 7, 8 of the optical fiber comprise V-shaped notches 21 in which the optical fiber is positioned, as may be seen in FIG. 5. A V-shaped notch improves the accuracy with which the fiber is positioned, since the fiber gets wedged against the sidewalls of the notch, regardless of its manufacturing tolerances.

After the optical fiber 4 has been positioned on the holders 7 and 8, it is fastened to each thereof, preferably by adhesive bonding. The segments of the optical fiber that are fastened to the holders 7, 8 are not drawn segments and have a non-narrowed diameter, typically between 100 μm and 150 μm.

Advantageously, the position of the optical fibers on the holders 7, 8 is controlled by a camera using a microscope lens.

Once the optical fiber has been fastened to the holders 7, 8, another optical fiber may be placed on the drawing apparatus in order to be drawn, then positioned on and fastened to the holders 7, 8.

Advantageously, a holder 7, 8 may comprise a plurality of V-shaped notches 21 allowing a plurality of optical fibers to be positioned thereon.

Also advantageously, a plurality of holders may be stacked vertically to form a plurality of tiers and thus allow a higher number of optical fibers to be positioned in the vacuum chamber. To do this, optical fibers are successively drawn and fastened to the first holder 7 and to the second holder 8. A first additional holder 7 and a second additional holder 8 are then fastened to the first and second holders 7, 8, preferably by adhesive bonding, and then drawn optical fibers are successively fastened to the additional holders. The procedure may be repeated to stack a higher number of additional holders, for example to obtain a stack of 5 or more holders, 10 or more holders, or 50 or more holders.

FIG. 5 shows a stack of two first holders 7 comprising a plurality of V-shaped notches 21 in which the optical fibers 4 are placed. The holders 7 are fastened together by an adhesive 22. The second holders 8 may be stacked in the same way.

The holders 7, 8, or in the case of stacking the stacked sets of holders 7, 8, are then fastened to a plate 9, preferably a metal plate. The plate 9 is then installed in the vacuum chamber 2.

Very precise positioning of the plurality of optical fibers 4 within the vacuum chamber 2 is thus obtained.

### Arrangement of the Waveguides

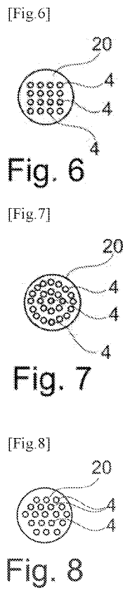

FIGS. 6 to 8 illustrate various possible configurations for the arrangement of the optical fibers 4. These configurations are not limited to optical fibers and are applicable to other types of waveguides.

The evanescent field of the light around the narrow segment of each waveguide decreases exponentially and, for small diameters of between 300 and 500 nm, becomes weak at typical distances of 1 μm from the exterior surface of the waveguide. Thus, the minimum spacing between each waveguide is preferably greater than 1 μm, and more preferably greater than 10 μm. However, the spacing between each waveguide may be less than or equal to 250 μm, 200 μm, 100 μm, 20 μm, 10 μm, 5 μm or 2 μm.

By way of example, in the case where the atomic cloud has a transverse extent of at least 2 mm around the narrow segments of the waveguides, it is possible to position 10×10 optical fibers in the atomic cloud while ensuring each optical fiber still has a large optical thickness, i.e. ensuring atoms around the fiber still exhibit a high level of absorption of light, without disrupting formation of a magneto-optic trap intended to trap the atomic cloud in proximity to the optical fibers.

A higher density of waveguides, of the order of 100×100 waveguides in the atomic cloud, may be obtained with other types of waveguides or with an atomic cloud of greater transverse extent.

It is advantageous to place the optical fibers in a compact configuration so as to maximize the number of fibers able to be enveloped by the atomic cloud.

As shown in FIG. 6, the optical fibers 4 may be assembled so as to be placed, viewed in cross section, at the nodes of a square grid of L rows of N fibers contained in the atomic cloud 20.

Alternatively, the fibers 4 may be arranged, viewed in cross section, on homothetic concentric lines, as illustrated in FIG. 7.

According to another advantageous variant, the fibers 4 are arranged, viewed in cross section, at the nodes of a hexagonal grid, as illustrated in FIG. 8.

### Fastening of the Carrier to the Vacuum Chamber

At the end of the process of drawing and fastening the optical fibers, a configuration that preferably is compact is obtained, for example one taking the form of an array of N×L nanofibers fastened to the holders 7, 8 or to the stack of holders 7, 8.

The holders 7, 8 are fastened to a plate 9, a metal plate for example, allowing them to be transported between the drawing apparatus 10 and the vacuum chamber 2. The plate 9 is then installed inside the vacuum chamber 2.

### Preparing the Atomic Cloud

In the context of the invention, the single atomic cloud 20 is advantageously prepared using an atomic trap configured to trap in proximity to the waveguides of the atoms introduced into the vacuum chamber through the inlet 3. The configuration of the atomic trap defines the dimensions of the atomic cloud.

Preferably, the atomic trap is a magneto-optical trap and comprises at least two longitudinal rectangular coils 24 placed on either side of the vacuum chamber 2 and extending in the longitudinal direction of the waveguides 4. The longitudinal rectangular coils 24 produce a magnetic-field gradient configured to trap the atoms of the atomic cloud 20.

Optionally, the length of the magneto-optical trap may be increased through use of a configuration further comprising at least two additional rectangular coils placed on either side of the vacuum chamber in a plane perpendicular to the plane formed by the transverse coils 24. The additional rectangular coils extend in a direction parallel to the coils 24.

A compression phase achieved through increase of the magnetic-field gradient may also be present. By increasing the slope of the magnetic-field gradient, the atomic cloud may be compressed to facilitate creation of the dipole traps around each waveguide and thereby increase the number of atoms in proximity to the waveguides.

One or more cooling laser beams are advantageously employed in combination with the coils.

According to a first alternative, three laser beams are oriented toward the narrower segment of the waveguides. Mirrors are placed perpendicular to the beams on the opposite side of the chamber in order to reflect the laser beams: three retroreflected laser beams are then obtained.

Preferably, two of the laser beams propagate in the same plane, making therein an angle of 90 °for example at their intersection, and the third laser beam propagates perpendicular to the plane of the first two laser beams through the intersection of the latter.

According to a second alternative, six non-retroreflected laser beams are oriented toward the narrower segment of the waveguides. Three first beams are oriented as the three laser beams of the first alternative, the other three each being oriented in a direction opposite to those of the first three beams.

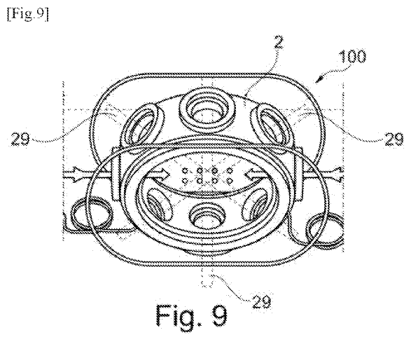

FIG. 9 shows three retroreflected laser beams 29 directed toward the narrower segment of the waveguides in the vacuum chamber 2.

Advantageously, the atomic cloud 20 has a maximum extent in the transverse direction of between 1 mm and 5 mm, and a length of between 0.5 cm and 5 cm and preferably of about 2 cm.

The dimensions of the atomic cloud 20 are chosen so that the atomic cloud covers the entirety of the narrow segments of the waveguides, and hence a single atomic cloud is sufficient to achieve the multiplexed quantum memory.

After the atomic cloud 20 has been prepared, dipole traps formed in the evanescent field of each waveguide are loaded. Preferably, it is a question of dipole traps employing two optical frequencies (detuned into the blue and into the red with respect to the atomic transition of the constituent atoms of the atomic cloud) and formed by injecting laser beams directly into the waveguides.

The dipole traps allow atoms to be trapped optically in the evanescent field of each waveguide by means of laser beams propagating through the waveguides.

Each waveguide then represents one independent quantum memory. Multiplexing of quantum memories is therefore achieved.

Other variants and improvements may be provided without however departing from the scope of the invention.

For example, the atoms of the atomic cloud may be atoms of an atomic element other than cesium, in particular rubidium.

1. A device for storing quantum information, comprising:
a vacuum chamber,
a plurality of waveguides that are configured to propagate light of wavelength λ and that each contain a segment of narrower cross section having a smallest transverse dimension less than λ, the plurality of waveguides extending into the vacuum chamber, and
an atomic trap configured to trap a single atomic cloud around the segment of narrower cross section of the waveguides.

2. The device as claimed in claim 1, the segment of narrower cross section of each waveguide being placed at less than 250 μm from a segment of narrower cross section of an adjacent waveguide and at greater than 1 μm.

3. The device as claimed in claim 1, the waveguides being placed, viewed in cross section, at the nodes of a square or hexagonal grid, or on concentric lines.

4. The device as claimed in claim 1, the segments of narrower cross section being parallel to one another.

5. The device as claimed in claim 1, the waveguides being optical fibers and the vacuum chamber comprising two seal-tight conduits configured to allow the waveguides to enter and exit.

6. (canceled)

7. The device as claimed in claim 1, the waveguides being fastened in the vacuum chamber to a first holder and to a second holder.

8. The device as claimed in claim 7, comprising a plurality of stacked first holders and of stacked second holders for positioning the guides at various levels in the vacuum chamber.

9. The device as claimed in claim 7, the first holder and second holder comprising a plurality of notches in which the guides are able to be at least partially received.

10. The device as claimed in claim 1, the waveguides being lithographically patterned nanoscopic structures.

11. The device as claimed in claim 1, the segment of narrower cross section of the waveguides being circular in cross section and having a diameter between 300 nm and 500 nm.

12. The device as claimed in claim 1, the atomic trap comprising two longitudinal coils, arranged outside the chamber and extending along the longitudinal axis of the waveguides on either side thereof, the longitudinal coils being configured to produce a magnetic-field gradient trapping the atomic cloud.

13. The device as claimed in claim 12, the atomic trap comprising two additional coils, arranged outside the chamber in a plane perpendicular to a plane containing the two longitudinal coils and extending along the longitudinal axis of the waveguides on either side thereof, the additional coils being configured to produce a magnetic-field gradient trapping the atomic cloud.

14. The device as claimed in claim 13, the longitudinal coils and/or the additional coils being rectangular coils.

15. The device as claimed in claim 1, the atomic trap comprising one or more lasers configured to cool the atomic cloud.

16. A method for manufacturing a device for storing quantum information as claimed in claim 5, comprising:
(a) hot drawing and fastening after drawing between two holders a plurality of optical fibers, so as to obtain the plurality of optical fibers having a segment of narrower cross section;
(b) placing the plurality of optical fibers in the vacuum chamber.

17. A method for storing quantum information as claimed in claim 1, comprising the steps of:
(a1) forming a vacuum in the vacuum chamber;
(b1) introducing a plurality of atoms, into the vacuum chamber; and
(c1) trapping the plurality of atoms around the segments of narrower cross section of the waveguides by means of the atomic trap to form the atomic cloud.

18. The method as claimed in claim 17, comprising, after step (c1), a step (d1) of propagating, through each waveguide, light of wavelength greater than the smallest transverse dimension of the segment of narrower cross section of the waveguides so as to create a dipole trap around each waveguide.

19. The method as claimed in claim 18, comprising, after step (d1), a step (el) of transferring quantum information between laser light propagating through each of the waveguides and a portion of the atomic cloud trapped around the segment of narrower cross section of each of the waveguides, in such a way as to achieve multiplexing of quantum memories.
